(19) United States
(12) Patent Application Publication
(10) Pub. No.: US 2026/0123520 A1
(43) Pub. Date: Apr. 30, 2026

(54) SEMICONDUCTOR PACKAGE

(71) Applicant: Samsung Electronics Co., Ltd., Suwon-si (KR)

(72) Inventors: Inhee Yoo, Suwon-si (KR); Hakmin Kim, Suwon-si (KR); Jaewoo Jeong, Suwon-si (KR)

(21) Appl. No.: 19/267,568

(22) Filed: Jul. 13, 2025

(30) Foreign Application Priority Data
Oct. 22, 2024 (KR) 10-2024-0144746

(51) Int. Cl. H01L 23/00; H01L 23/29; H01L 23/31; H01L 23/498; H01L 25/065

(52) U.S. Cl. CPC H10W 74/117; H10W 74/47; H10W 90/00; H10W 90/701; H10W 72/07302; H10W 72/387; H10W 72/884; H10W 90/24; H10W 90/732; H10W 90/734; H10W 90/752; H10W 90/754

(57) ABSTRACT

Provided is a semiconductor package, the semiconductor package including: a package substrate having an upper surface on which a plurality of bonding pads are arranged; a semiconductor chip disposed on the package substrate, and having an upper surface on which a plurality of chip pads are arranged; an adhesive layer extending onto the upper surface of the package substrate between the semiconductor chip and the package substrate; a dam structure disposed around the adhesive layer, and surrounding a side surface of the adhesive layer; and external connection bumps disposed below the package substrate, and electrically connected to the plurality of bonding pads, wherein the external connection bumps are located below a region covered by the adhesive layer of the package substrate, and an area of the adhesive layer is greater than an area of a region in which the external bumps are disposed.

### CROSS-REFERENCE TO RELATED APPLICATION(S)

This application claims the benefit of priority under 35 U.S.C. § 119 to Korean Patent Application No. 10-2024-0144746, filed on Oct. 22, 2024, in the Korean Intellectual Property Office, the entire disclosure of which is incorporated herein by reference for all purposes.

### BACKGROUND

The present inventive concept relates to a semiconductor package.

In order to increase consumer satisfaction and secure continuous purchasing power, in the semiconductor packaging field, there is also a need to develop semiconductor packages meeting the quality and reliability standards required by the industry. Accordingly, packages and modules comprised of a combination of a variety of different materials are required to maintain the original degree of quality and performance for a certain period of time without failure.

### SUMMARY

An aspect of the present inventive concept is to provide a semiconductor package having improved reliability of external connection bumps.

According to an aspect of the present inventive concept, provided is a semiconductor package, the semiconductor package including: a package substrate having an upper surface on which a plurality of bonding pads are arranged; a semiconductor chip disposed on the package substrate, and having an upper surface on which a plurality of chip pads are arranged; a plurality of bonding wires electrically connecting the plurality of bonding pads to the plurality of chip pads; an adhesive layer extending onto the upper surface of the package substrate between the semiconductor chip and the package substrate; a dam structure disposed around the adhesive layer, and surrounding a side surface of the adhesive layer; a molded layer disposed on the upper surface of the package substrate, and covering at least a portion of each of the semiconductor chip and the plurality of bonding wires; and external connection bumps disposed below the package substrate, and electrically connected to the plurality of bonding pads, wherein the external connection bumps are located below a region covered by the adhesive layer of the package substrate, and an area of the adhesive layer is greater than an area of a region in which the external bumps are located.

According to an aspect of the present inventive concept, provided is a semiconductor package, the semiconductor package including: a package substrate having an upper surface on which a plurality of bonding pads are arranged; a semiconductor chip mounted on the upper surface of the package substrate, and having an upper surface on which a plurality of chip pads are arranged; an adhesive layer disposed below the semiconductor chip, and extending onto the upper surface of the package substrate; a dam structure disposed on the package substrate, and surrounding a side surface of the adhesive layer; a plurality of bonding wires electrically connecting the plurality of bonding pads to the plurality of chip pads; and a molded layer disposed on the upper surface of the package substrate, and covering at least a portion of each of the semiconductor chip and the plurality of bonding wires, wherein a width of the adhesive layer and a width of the dam structure are greater than a width of the semiconductor chip.

According to an aspect of the present inventive concept, provided is a semiconductor package, the semiconductor package including: a package substrate having an upper surface on which a plurality of bonding pads are arranged; a semiconductor chip disposed on the package substrate, and including an upper surface on which a plurality of chip pads are arranged, the semiconductor chip having a first area; external connection bumps disposed below the package substrate, and electrically connected to the plurality of bonding pads; an adhesive film disposed between the semiconductor chip and the package substrate and having an area equal to that of the first area; a polymer layer disposed on the package substrate, and surrounding a side surface of the adhesive film, the polymer layer having a second area; a dam structure protruding from the package substrate, and having an inner surface in contact with a side surface of the polymer layer; a plurality of bonding wires electrically connecting the plurality of bonding pads to the plurality of chip pads; and a molded layer disposed on the upper surface of the package substrate, and covering at least a portion of each of the semiconductor chip and the plurality of bonding wires.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view of a semiconductor package according to an example embodiment, and FIG. 1B is a cross-sectional view taken along line I1-I1′ of FIG. 1A;

FIG. 2 is a cross-sectional view illustrating a semiconductor package according to an exemplary modified example;

FIG. 3 is a cross-sectional view and a partially enlarged view illustrating a semiconductor package of an exemplary modified example;

FIG. 4 is a cross-sectional view and a partially enlarged view illustrating a semiconductor package of an exemplary modified example;

FIG. 5 is a plan view illustrating a semiconductor package according to an exemplary modified example;

FIG. 6A is a plan view illustrating a semiconductor package according to an example embodiment, and FIG. 6B is a cross-sectional view taken along line I2-I2′ of FIG. 6A;

FIG. 7A is a plan view illustrating a semiconductor package according to an example embodiment, and FIG. 7B is a cross-sectional view taken along line I3-I3′ of FIG. 7A;

FIG. 8 is a cross-sectional view and a partially enlarged view illustrating a semiconductor package of an exemplary modified example;

FIG. 9 is a cross-sectional view and a partially enlarged view illustrating a semiconductor package of an exemplary modified example;

FIGS. 10A to 10C are drawings illustrating a manufacturing process of a semiconductor package according to an example embodiment; and

FIGS. 11A to 11B are drawings illustrating a manufacturing process of a semiconductor package according to an example embodiment.

### DETAILED DESCRIPTION

Hereinafter, preferred example embodiments of the present inventive concept will be described with reference to the accompanying drawings. Like reference characters refer to like elements throughout. Unless otherwise specified, in this specification, terms such as “upper,” “upper surface,” “lower,” “lower surface,” “side” and the like are based on the drawings, and actually, may vary depending on the direction in which the components are disposed.

In addition, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. Additionally, terms referenced by a specific ordinal number (for example, “first” in a particular claim) may be described elsewhere with a different ordinal number (for example, “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

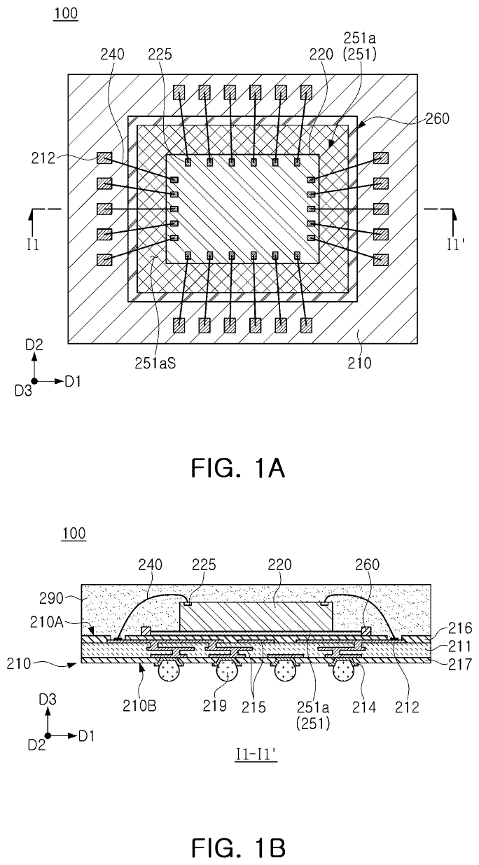

FIG. 1A is a plan view of a semiconductor package according to an example embodiment, and FIG. 1B is a cross-sectional view taken along line I1-I1′ of FIG. 1A.

Referring to FIGS. 1A and 1B, a semiconductor package 100 of an example embodiment may include a package substrate 210, a semiconductor chip (or ‘chip structure’) 220, an adhesive layer 251a, and a dam structure 260. According to an example embodiment, the semiconductor package 100 may further include bonding wires 240, a molded layer 290, and external connection bumps 219.

The package substrate 210 may include a substrate body 211 in which a plurality of insulating layers are stacked, and a wiring circuit 215 having conductive vias and conductive patterns formed on each of the insulating layers.

The package substrate 210 may include a plurality of bonding pads 212 disposed on an upper surface 210A of the substrate body 211 and a plurality of external connection pads 214 disposed on a lower surface 210B of the substrate body 211, and the wiring circuit 215 may electrically connect the plurality of bonding pads 212 and the plurality of external connection pads 214.

The plurality of bonding pads 212 may be disposed on the exterior of the dam structure 260, and may not overlap a region in which external connection bumps 219 are disposed in a direction perpendicular to the package substrate 210 (e.g., D3 direction). For example, the plurality of bonding pads 212 may be positioned adjacent to each external side surface of the dam structure 260, and may surround the exterior of the dam structure 260.

In some example embodiments, the substrate body 211 may include a resin-series insulating layer such as an epoxy resin, a bakelite resin, a paper epoxy, a glass epoxy, or the like. The wiring circuit 215 may be formed of gold (Au), silver (Ag), platinum (Pt), aluminum (Al), copper (Cu), or the like. For example, the package substrate 210 may include a printed circuit board (PCB). In another example embodiment, the package substrate 210 may be a redistribution substrate having a circuit pattern. The substrate body 211 may include an inorganic insulating layer such as silicon oxide or silicon nitride, or a photosensitive organic insulating material such as a photo imageable dielectric (PID).

In some example embodiments, the package substrate 210 may include a solder resist layer 216 disposed on the upper surface 210A. The solder resist layer 216 may have a plurality of openings exposing a region of each of the plurality of bonding pads 212. In addition, the package substrate 210 may include a solder resist layer 217 disposed on the lower surface 210B. The solder resist layer 217 may have a plurality of openings in which the plurality of external connection pads 214 are provided.

The semiconductor chip 220 is disposed on the upper surface 210A of the package substrate 210, and has an upper surface on which a plurality of chip pads 225 are arranged. The chip pad 225 of the semiconductor chip 220 may be electrically connected to the bonding pad 212 of the package substrate 210 by a bonding wire 240.

The semiconductor chip 220 may include, for example, silicon (Si), but the present inventive concept is not limited thereto, and the semiconductor chip 220 may include a semiconductor element such as germanium (Ge), or a compound semiconductor such as silicon carbide (SiC), gallium arsenide (GaAs), indium arsenide (InAs), and indium phosphide (InP). In some example embodiments, the semiconductor chip 220 may have a silicon on insulator (SOI) structure. An active region, for example, a well doped with impurities, or a structure doped with impurities may be formed on the upper surface (i.e., also referred to as an “active surface”) of the semiconductor chip 220. Such an active region may be defined by an isolation structure, such as a shallow trench isolation (STI) structure. The lower surface of the semiconductor chip 220 may be referred to as an inactive surface. Herein, the inactive surface may be the surface which does not include any devices, and the active surface may be the surface on which devices are formed.

The semiconductor chip 220 may include a system LSI, a flash memory, a DRAM, an SRAM, an EEPROM, a PRAM, an MRAM, or an RRAM. Specifically, the semiconductor chip 220 may include various individual devices formed in the active region. The individual devices may include, for example, a metal-oxide-semiconductor field effect transistor (MOSFET) such as a complementary metal-oxide-semiconductor transistor (CMOS transistor), a passive device, and the like. The semiconductor chip 220 may include a wiring structure layer in which a plurality of individual devices are connected. The wiring structure layer may include an insulating layer and a metal wiring layer formed on the insulating layer. The chip pads 225 may be formed in some regions of the metal wiring layer.

The plurality of bonding wires 240 may electrically connect a plurality of bonding pads 212 on an upper surface 210A of the package substrate and a plurality of chip pads 225 on an upper surface of the semiconductor chip 220. For example, a bonding wire 240 may extend from each of the chip pads 225 to a corresponding one of the bonding pads 212. These wires 240 may be formed through a wire bonding process, and may be conductive wires including a conductive material such as gold (Au), copper (Cu), etc. A molded layer 290 may be formed on the upper surface 210A of the package substrate 210. The molded layer 290 may be disposed on the upper surface 210A of the package substrate 210 to cover at least a portion of the semiconductor chip 220 and the bonding wires 240. The molded layer 290 may contact the upper surface 210A of the package substrate 210, upper and side surfaces of the semiconductor chip 220, and the bonding wires 240.

The molded layer 290 may be formed of a resin. The molded layer 290 may include, for example, a thermosetting resin such as an epoxy resin, a thermoplastic resin such as a polyimide, or a prepreg, ABF, FR-4, BT, Epoxy Molding Compound (EMC), or the like. An elastic modulus of the molded layer 290 at room temperature may be greater than an elastic modulus of the adhesive layer 251a. For example, the elastic modulus of the molded layer 290 at room temperature may range from about 18,000 mpa to 30,000 mpa. The elastic modulus of the adhesive layer 251a at room temperature may range from about 2,500 MPa to 3,500 MPa. Since the adhesive layer 251a has an elastic modulus that is about 15,000 MPa or lower than that of the molded layer 290, fatigue stress due to repeated deformation caused by contraction and expansion due to a difference in internal thermal expansion coefficients may be reduced even when a temperature change occurs in the package. Therefore, the reliability related to the temperature change of the external connection bumps 219 may be increased.

The adhesive layer 251a may attach the semiconductor chip 220 to the upper surface 210A of the package substrate 210. Unlike the conventional film type that is attached to the lower surface of the semiconductor chip 220, the adhesive layer 251a may be formed by being directly coated to the upper surface 210A of the package substrate 210. The adhesive layer 251a may be disposed below the semiconductor chip 220, and may extend onto the upper surface 210A of the package substrate 210. The adhesive layer 251a may have portions extending from each of four edges of the semiconductor chip 220 on the upper surface 210A of the package substrate. The adhesive layer 251a may contact an upper surface of the solder resist layer 216.

A film-type adhesive member, such as a die attach film, is used by being manufactured in advance to a certain thickness and then attached to a wafer. In particular, since the film-type adhesive member should be able to be treated by a series of processes, such as an attachment process, it is manufactured and attached to a size substantially the same as the size of the semiconductor chip 220. In contrast thereto, the adhesive layer 251a employed in the present embodiment is a liquid adhesive member that is applied directly between the semiconductor chip 220 and the package substrate 210, and therefore may have a width larger than the size of the semiconductor chip 220.

An area of the adhesive layer 251a may be increased within a range in which no other changes in the package structure occur (e.g., a range in which the bonding pad 212 and the adhesive layer 251a do not overlap). In example embodiments, the external connection bumps 219 may overlap with the adhesive layer 251a in a vertical direction (e.g., D3 direction). For example, the area of the adhesive layer 251a may be substantially the same as the area in which the external connection bumps 219 are disposed. Even if the area of the adhesive layer 251a is substantially the same as the area in which the external connection bumps 219 are disposed, the area of the adhesive layer 251a may still be larger than the area of the semiconductor chip 220 when viewed in plan view. Since the adhesive layer 251a is present in the region overlapping the region in which the plurality of external connection bumps 219 are disposed, the durability of the external connection bumps 219 against temperature changes may be increased.

Furthermore, the area of the adhesive layer 251a may be larger than the area in which the external connection bumps 219 are disposed. In some example embodiments, the area of the adhesive layer 251a may be in the range of 110% to 130% of the area in which the external connection bumps 219 are disposed.

In another aspect, as illustrated in FIG. 1A, it may be described that the adhesive layer 251a has portions 251aS extending from each of the four edges of the semiconductor chip 220 along the upper surface 210A of the package substrate 210. In example embodiments, a distance that each of the portions 251aS extends from a respective side surface may be the same or different from each other.

By expanding the adhesive layer 251a along the upper surface 210A of the package substrate 210 to have an area larger than that of the semiconductor chip 220, the upper surface of the adhesive layer 251a having portions 251aS extending from each of the four edges of the semiconductor chip 220 may vertically overlap a side surface of the semiconductor chip 220.

By overlapping the upper surface of the adhesive layer 251a and the side surface of the semiconductor chip 220 in a direction perpendicular to each other (e.g., D3 direction), the stress concentrated in a vertical direction (e.g., D3 direction) at the boundary of the semiconductor chip 220 may be distributed in horizontal directions (e.g., D1 direction and D2 direction) through the extended portion 251aS of the adhesive layer 251a, thereby increasing the durability of the external connection bump 219 against temperature changes.

As described above, the adhesive layer 251a having an area larger than that of the semiconductor chip 220 may serve as a buffer layer that can alleviate the occurrence of defects due to mismatch of expansion and condensation caused by thermal changes that occur when the semiconductor package 100 is mounted on a main board.

The dam structure 260 may be disposed around the adhesive layer 251 applied to the upper surface 210A of the package substrate 210, and may be in contact with the side surface of the adhesive layer 251. For example, a lower surface of the dam structure 260 may contact an upper surface of the solder resist layer 216, and may be disposed at the same vertical level as a lower surface of the adhesive layer 251. In example embodiments, side surfaces of the dam structure 260 may be substantially perpendicular to the upper surface of the solder resist layer 216. The dam structure 260 may represent a boundary of a region in which the adhesive layer 251 is disposed so that the adhesive layer 251 is applied at an accurate position. For example, the dam structure 260 may define the region in which the adhesive layer 251 is formed. The dam structure 260 may be comprised of the same material as a solder resist layer 216 disposed on the upper surface 210A of the package substrate 210. For example, a constituent material of the dam structure 260 may be the same as a constituent material of the solder resist layer 216. As used herein, the label 251 may be used interchangeably with the label 251a.

The dam structure 260 may be a solder resist pattern formed of solder resist. For example, a solder mask insulating ink may be applied to the upper surface 210A of the package substrate 210 by a screen printing method or inkjet printing, and then cured with heat, UV, or IR to form a dam structure 260, which is a solder resist pattern.

A thickness in a vertical direction (e.g., D3 direction) of the dam structure 260 may be greater than a thickness in a vertical direction (e.g., D3 direction) of the adhesive layer 251a. For example, an upper surface of the dam structure 260 may be at a higher vertical level than an upper surface of the adhesive layer 251. For example, when the adhesive layer 251a is comprised of a liquid adhesive material, the dam may serve to limit the liquid adhesive material from being applied to the region in which the bonding pad 212 is disposed.

For example, the thickness of the dam may be in the range of about 10 μm to 30 μm. When the thickness of the dam is less than 10 μm, the liquid adhesive material may flow to a region in which the bonding pad 212 is disposed. In this case, the adhesive material may be applied to the bonding pad 212, and a defect may occur.

When the dam thickness exceeds 30 μm, the structural stability of the package structure may deteriorate. In addition, the greater the thickness, the more likely it is that the dam will collapse or break, resulting in defects.

A width occupied by the adhesive layer 251a and the dam structure 260 in the horizontal directions (e.g., D1 direction and D2 direction) may be larger than a width of the semiconductor chip 220 in the horizontal directions (e.g., D1 direction and D2 direction). Therefore, the stress concentrated at the boundary of the semiconductor chip 220 may be dispersed.

Since the dam structure 260 serves to limit the boundary of the adhesive layer 251a, the side surface of the adhesive layer 251a may be in contact with the inner surface of the dam structure 260. Accordingly, a portion of the lower surface of the molded layer 290 may be disposed along a groove enclosed by a portion of the upper surface of the adhesive layer 251a, the side surface of the semiconductor chip 220, and the inner surface of the dam structure 260.

Each of the plurality of external connection bumps 219 may be disposed on a plurality of external connection pads 214 disposed below the package substrate 210. The plurality of external connection bumps 219 may disposed in a region below the package substrate 210 covered with the adhesive layer 251a. The direction (e.g., D3 direction) applied due to a difference in thermal expansion coefficients between the semiconductor chip 220 and the molded layer 290 may be applied to the external connection bump 219 in an alleviated state by the adhesive layer 251a.

A size of a region in which the external connection bumps 219 are disposed may be equal to or larger than the size of the semiconductor chip 220. For example, even if the region in which the external connection bumps 219 are disposed is larger than the semiconductor chip 220, due to a low elastic modulus of the adhesive layer 251a on the upper surface 210A of the package substrate 210, a deformation rate of the external connection bumps 219 caused by a difference in thermal expansion coefficient due to temperature change between the semiconductor chip 220 and the molded layer 290 may be reduced. In addition, it may be the same even if the boundary of the semiconductor chip 220 overlaps external connection bumps 219 disposed at the outermost side among the external connection bumps 219 in a direction perpendicular to the package substrate 210 (e.g., D3 direction).

A plurality of external connection bumps 219 may be electrically connected to a plurality of bonding pads of an external device or system, thereby, the semiconductor package 100 may be electrically connected to an external system.

The plurality of external connection bumps 219 may have a shape that can be obtained through a reflow process, for example, a spherical shape or a nearly spherical shape (e.g., an elliptical sphere). Depending on the type of the plurality of external connection bumps 219, the semiconductor package 100 may include a ball grid array (BGA), a fine ball-grid array (FBGA), or a land grid array (LGA) form.

A plurality of external connection pads 214 may be connected to a lowermost wiring circuit 215. For example, the plurality of external connection pads 214 may include underbump metallurgy (UBM). Each of the plurality of external connection bumps 219 may include a eutectic metal such as a solder ball. For example, the solder ball may include at least one of tin (Sn), lead (Pb), nickel (Ni), gold (Au), silver (Ag), copper (Cu), bismuth (Bi), and combinations thereof, and may be formed by a soldering device.

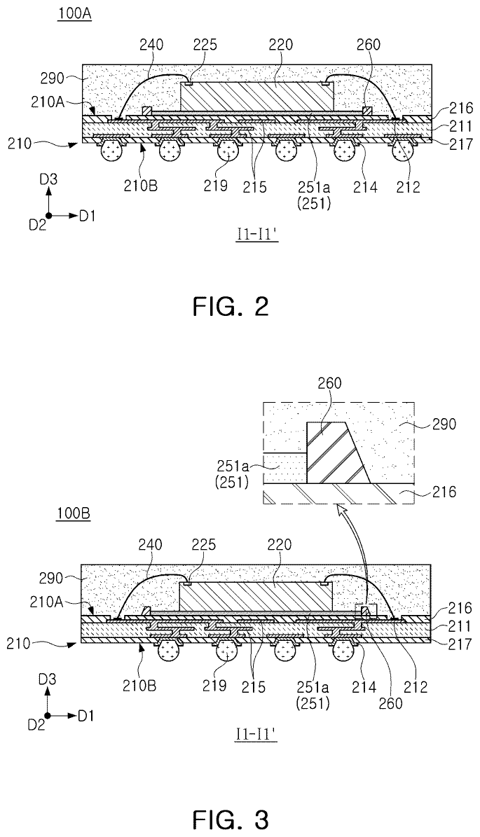

FIG. 2 is a cross-sectional view illustrating a semiconductor package of an exemplary modified example.

Referring to FIG. 2, a semiconductor package 100A of a modified example may have the same features as those described with reference to FIGS. 1A and 1B, except that a region in which an external connection bumps 219 are disposed is greater than a region in which an adhesive layer 251a is disposed.

In a modified example, the region in which the external connection bumps 219 are disposed may overlap in a direction perpendicular to the package substrate 210. The external connection bumps 219 may be distributed more than in the semiconductor package 100 of the example embodiment of FIG. 1, so that more electrical connections may be attempted with the exterior of the semiconductor package. For example, some of the external connection bumps 219 may overlap in the vertical direction (e.g., D3 direction) with the adhesive layer 251a, while others of the external connection bumps 210 may not overlap in the vertical direction (e.g., D3 direction) with the adhesive layer 251a. In addition, since the adhesive layer 251a is still disposed in a direction perpendicular to the semiconductor chip 220, the stress applied in the vertical direction to the external connection bumps 219 during periodic temperature changes during the user's usage environment may be dispersed.

FIG. 3 is a cross-sectional view and a partially enlarged view illustrating a semiconductor package of an example embodiment.

Referring to FIG. 3, a semiconductor package 100B of the example embodiment may have the same features as those described with reference to FIGS. 1A and 1B, except that a cross-section of a dam structure 260 has a trapezoidal shape. For example, an inner side surface of the dam structure 260 may be perpendicular to the upper surface of the solder resist layer 216, and the outer side surface of the dam structure 260 may form an obtuse angle with respect to the upper surface of the solder resist layer 216.

In an example embodiment, for example, when the adhesive layer 251a is applied in a liquid state, stress applied to a lower end of the dam in the horizontal direction (e.g., D1 direction and D2 direction) may be effectively distributed to provide stronger resistance in a lower portion of the dam. In addition, since the lower portion of the dam is wide and an upper portion of the dam is narrow, the pressure applied by the adhesive layer 251 may be withstood more efficiently, thereby increasing structural stability. In addition, if the lower portion of the dam is wide, a contact surface with the upper surface 210A of the package substrate increases, which can reduce the risk of the dam slipping or collapsing. Furthermore, it can provide structural efficiency by reducing material costs as an amount of material used may be reduced compared to a dam having a rectangular cross-section of the same height.

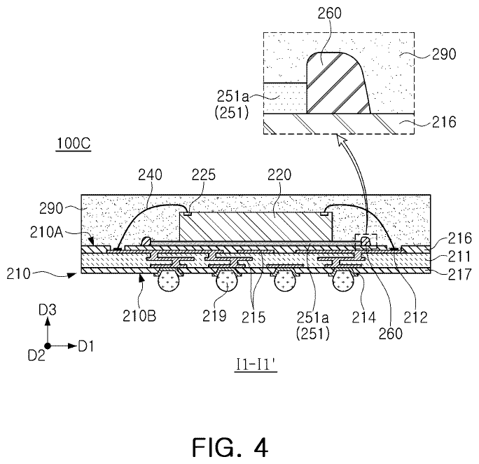

FIG. 4 is a cross-sectional view and a partially enlarged view illustrating a semiconductor package of an exemplary modified example.

Referring to FIG. 4, a semiconductor package 100C of a modified example may have features identical or similar to those described with reference to FIGS. 1A, 1B, and 3, except that upper edges of a cross-section of a dam structure 260 are curved.

When forming a dam structure 260, even if the cross-section of the dam is not exactly a trapezoidal shape, it can be formed substantially the same as this. Still, the dam may have a cross-section with a shape of which a width thereof gradually decreases in a direction toward the molded layer on the package substrate and have characteristics accordingly (see FIG. 3).

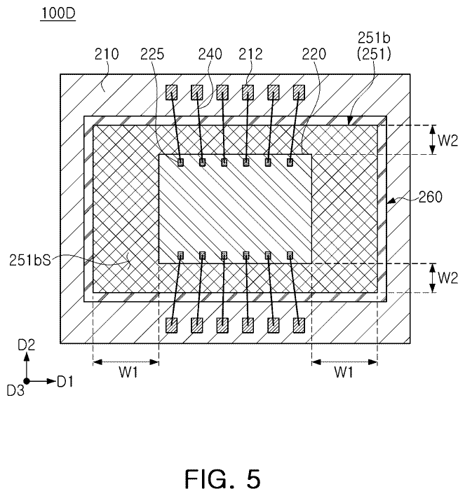

FIG. 5 is a plan view illustrating a semiconductor package of an exemplary modified example.

As illustrated in FIG. 5, among the extended portions, portions extending from two edges of the semiconductor chip, opposing each other in a first direction (e.g., D1 direction) may have a first width W1, and portions extending from the other two edges thereof, opposing each other in a second direction (e.g., D2 direction) may have a second width W2, smaller than the first width W1, respectively.

The widths W1 and W2 of the extended portions may be determined by the arrangement of the bonding pads 212. The plurality of bonding pads 212 may be arranged in a region, adjacent to two opposing edges of a semiconductor chip having a first width W1, and may not be arranged in a region, adjacent to the other two edges of the semiconductor chip.

As in the present embodiment, when the plurality of bonding pads 212 are arranged in a region adjacent to edges of a semiconductor chip 220 and opposing each other in a second direction (e.g., D2 direction), and are not arranged in a region adjacent to the other two edges thereof and opposing each other in a first direction (e.g., D1 direction), portions extending from the two edges, opposing each other in the first direction (e.g., D1 direction) may be extended to a sufficient width, while portions extending from the other two edges, opposing each other in the second direction (e.g., D2 direction) may be disposed to be spaced apart from the bonding pads 212 by a certain distance.

As described above, the widths W1 and W2 of the extended portions 251bS of the adhesive layer 251b may be designed differently depending on the arrangement of the bonding pads 212.

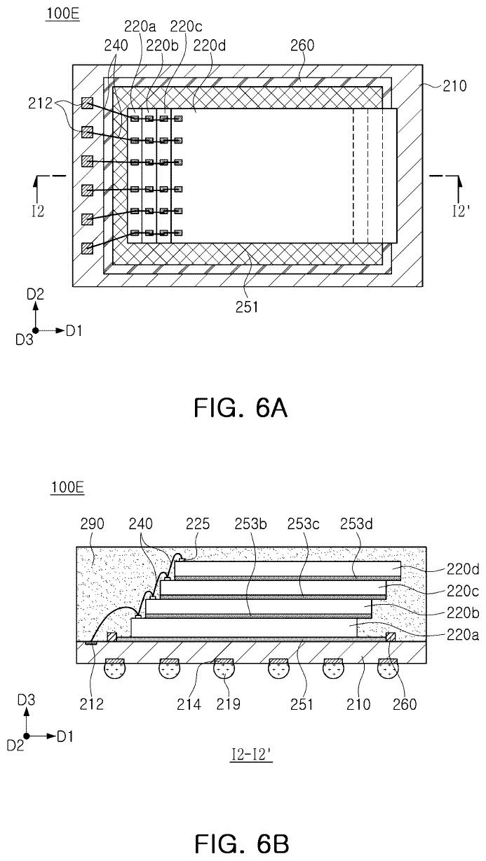

FIG. 6A is a plan view illustrating a semiconductor package according to an example embodiment, and FIG. 6B is a cross-sectional view taken along line I2-I2′ of FIG. 6A.

Referring to FIGS. 6A and 6B, a semiconductor package 100E according to the present embodiment may be understood to have a structure similar to the semiconductor package 100 illustrated in FIGS. 1A and 1B, except that the semiconductor package 100E includes a plurality of stacked semiconductor chips 220a, 220b, 220c, and 220d. Accordingly, the description of the semiconductor package 100 illustrated in FIGS. 1A and 1B may be combined with the description of the semiconductor package 100E according to the present embodiment, unless otherwise specifically stated.

The semiconductor package 100E may include a package substrate 210, a chip stack in which a plurality of semiconductor chips 220a, 220b, 220c, and 220d are stacked on the upper surface of the package substrate 210, and a molded layer 290 covering the chip stack.

The package substrate 210 may be a printed circuit board (PCB) having a wiring circuit (not shown) as described above. The package substrate 210 may have a structure in which an insulating film and a wiring layer comprising a wiring circuit are alternately stacked. External connection pads 214 connected to the wiring circuit may be disposed on a lower surface of the package substrate 210, and external connection bumps 219 may be respectively disposed on the external connection pads 214. A bonding pad 212 may be included in a region of the upper surface of the package substrate 210.

It is exemplified that the chip stack includes four semiconductor chips 220a, 220b, 220c, and 220d, stacked in a direction perpendicular to the upper surface of the package substrate 210 (e.g., D3 direction), but the present inventive concept is not limited thereto. For example, the chip stack may include a different number of semiconductor chips (e.g., 8 or 16).

In the present embodiment, the first to fourth semiconductor chips 220a, 220b, 220c, and 220d are stacked in a structure that is offset in a first direction (e.g., D1 direction) on the upper surface of the package substrate 210. For example, the second semiconductor chip 220b may be stacked to be offset in the first direction (e.g., D1 direction), and in this manner, the first to fourth semiconductor chips 220a, 220b, 220c, and 220d may have an upwardly inclined step shape.

Exposed upper surface regions of the first to fourth semiconductor chips 220a, 220b, 220c, and 220d may be active surfaces. For example, chip pads 225 may be disposed on the exposed upper surface regions of the first to fourth semiconductor chips 220a, 220b, 220c, and 220d, and may be arranged along a second direction (e.g., D2 direction) in a region adjacent to an edge of each of the exposed upper surface regions. The first to fourth semiconductor chips 220a, 220b, 220c, and 220d may be connected between adjacent semiconductor chips by bonding wires 240, and the chip pads 225 of the first semiconductor chip 220 may be connected to the bonding pads 212, respectively.

In this stacking process, inter-chip adhesive films 253b, 253c, and 253d may be attached to the lower surfaces of the second to fourth semiconductor chips 220b, 220c, and 220d with an area equal to the area of each chip.

The package substrate 210 may include an adhesive layer 251 and a dam structure 260 on the upper surface. The adhesive layer 251 may have an area larger than the area of the first semiconductor chip 220a. Similarly to the previous embodiments, by expanding the adhesive layer 251 along the upper surface of the package substrate 210 to have an area larger than that of the semiconductor chip 220, stress concentrated in a vertical direction (e.g., D3 direction) at a boundary of the semiconductor chip 220 may be distributed in horizontal directions (e.g., D1 direction and D2 direction) through the extended portion of the adhesive layer 251 (see, e.g., extended portion 251aS in FIG. 1), thereby increasing the durability of the external connection bump 219 against temperature changes.

In some example embodiments, the plurality of stacked semiconductor chips 220a, 220b, 220c, and 220d may be the same type of semiconductor chips. For example, the plurality of semiconductor chips may be memory semiconductor chips. The memory chip may be a volatile memory semiconductor chip, such as, for example, a dynamic random access memory (DRAM) or a static random access memory (SRAM), or a nonvolatile memory semiconductor chip, such as a phase-change random access memory (PRAM), a magnetoresistive random access memory (MRAM), a ferroelectric random access memory (FeRAM), or a resistive random access memory (RRAM). In some example embodiments, the plurality of semiconductor chips may be flash memory, for example, a NAND flash memory.

In other example embodiments, the plurality of stacked semiconductor chips may include different types of semiconductor chips. For example, one portion of the semiconductor chips among the plurality of semiconductor chips may be logic chips, and the other portion of the semiconductor chips among the plurality of semiconductor chips may be memory chips. For example, the logic chip may be a central processing unit (CPU) chip, a graphics processing unit (GPU) chip, or an application processor (AP) chip.

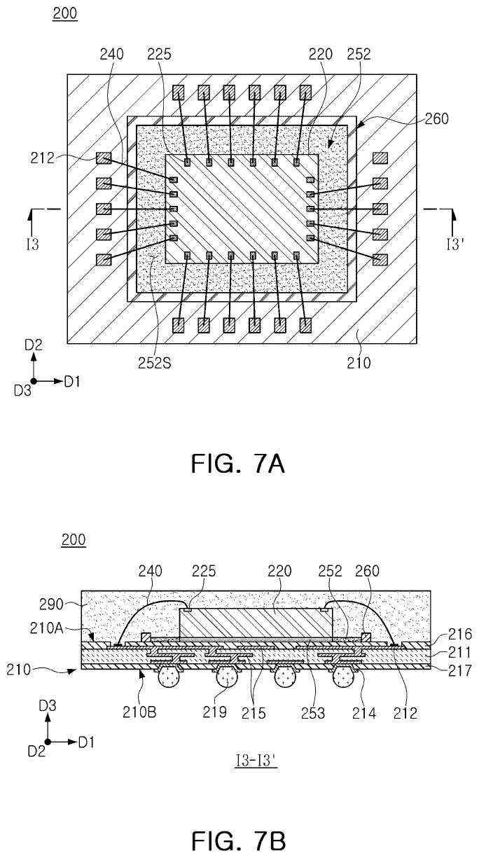

FIG. 7A is a plan view illustrating a semiconductor package according to an example embodiment, and FIG. 7B is a cross-sectional view taken along line I3-I3′ of FIG. 7A.

Referring to FIGS. 7A and 7B, a semiconductor package 200 of the example embodiment may have the same features as those described with reference to FIGS. 1A and 1B, except that the semiconductor package 200 includes an adhesive film 253 and a polymer layer 252, instead of an adhesive layer (see, e.g., adhesive layer 251 of FIG. 1).

A semiconductor chip 220 having a lower surface to which an adhesive film 253 is attached is prepared, and the semiconductor chip 220 to which the adhesive film 253 is attached may be mounted on a package substrate 210.

The adhesive film 253 may be attached to a lower surface of a wafer at the wafer level before being cut into semiconductor chips 220, and may be cut together with the semiconductor chips 220. Therefore, the adhesive film 253 may have an area corresponding to the semiconductor chips 220. After bonding the adhesive films 253, the semiconductor chip 220 may be bonded to the package substrate 210 by applying heat to harden the adhesive film 253.

Next, a polymer layer 252 may be applied between the dam structure and the adhesive film 253 on the lower surface of the semiconductor chip. The polymer layer 252 may include an insulating polymer material similar to the adhesive film 253. For example, the polymer layer 252 may include an insulating polymer material such as an epoxy resin.

An area in which the polymer layer 252 and the adhesive film 253 are disposed may be larger than an area of the semiconductor chip 220. Similarly to the previous example embodiments, by disposing a dam structure 260 on the upper surface 210A of the package substrate 210 to have an area, larger than the area of the semiconductor chip 220 (or the adhesive film 253), by expanding an area of the polymer layer 252 and the adhesive film 253, stress concentrated in a vertical direction (e.g., D3 direction) at a boundary of the semiconductor chip 220 may be distributed in horizontal directions (e.g., D1 direction and D2 direction) through the extended portion 252S of the polymer layer 252, thereby increasing the durability of the external connection bump 219 against temperature changes.

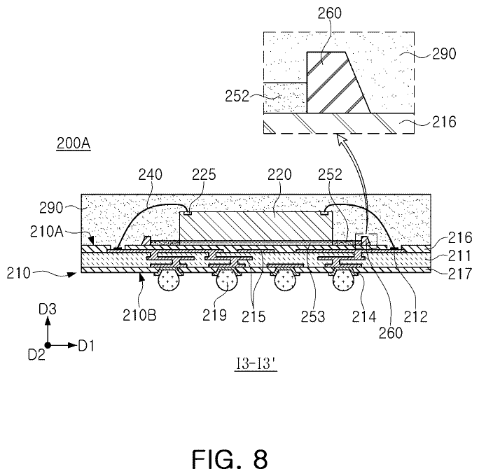

FIG. 8 is a cross-sectional view and a partially enlarged view illustrating a semiconductor package of an exemplary modified example.

Referring to FIG. 8, a semiconductor package 200A of a modified example may have the same features as those described with reference to FIGS. 1A, 1B, and 3, except that a polymer layer 252 and an adhesive film 253 are disposed instead of an adhesive layer 251.

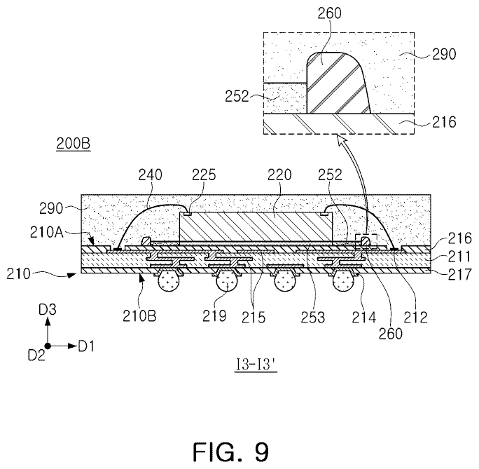

FIG. 9 is a cross-sectional view and a partially enlarged view illustrating a semiconductor package of an exemplary modified example.

Referring to FIG. 9, a semiconductor package 200B of a modified example may have the same features as those described with reference to FIGS. 1A, 1B, and 4, except that a polymer layer 252 and an adhesive film 253 are disposed instead of an adhesive layer 251.

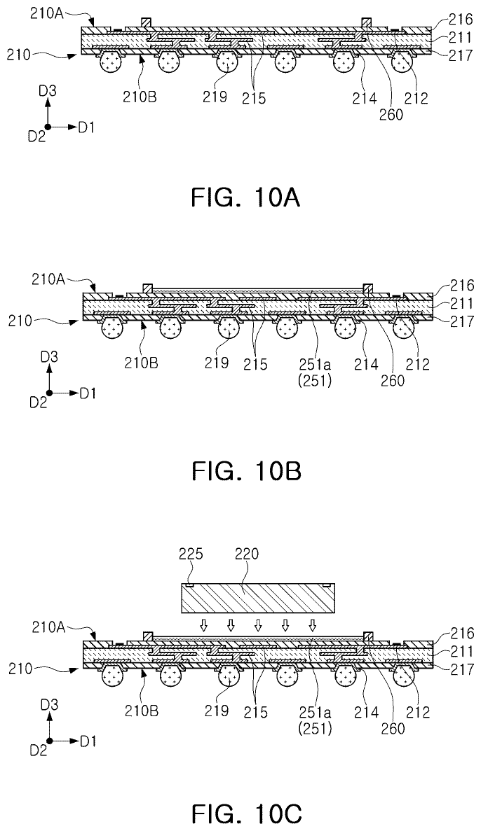

FIGS. 10A to 10C are drawings illustrating a manufacturing process of a semiconductor package according to an example embodiment. FIGS. 10A to 10C schematically illustrate a manufacturing process of a semiconductor package 100 according to the exemplary embodiment illustrated in FIGS. 1A to 1B.

Referring to FIG. 10A, a substrate body 211 on which a plurality of insulating layers are stacked and a wiring circuit 215 having conductive vias and conductive patterns on an insulating layer of the substrate body 211 may be formed. The package substrate 210 may include a plurality of bonding pads 212 disposed on an upper surface 210A of the substrate body 211 and a plurality of external connection pads 214 disposed on a lower surface 210B of the substrate body 211, and the wiring circuit 215 may electrically connect the plurality of bonding pads 212 and the plurality of external connection pads 214.

A solder resist layer 216 having a plurality of openings formed on the substrate body 211 may be formed. The solder resist layer 216 may be formed, for example, by entirely applying a photo-imageable solder resist material to the upper surface 210A of the package substrate 210 by a screen printing method, a spray coating method, or the like, or adhering a film-type solder resist material using a laminating method.

The dam structure 260 may be formed by applying a solder mask insulating ink on the upper surface 210A of the package substrate 210 by screen printing or inkjet printing, and then curing the same with heat, UV, or IR.

Referring to FIG. 10B, an adhesive layer 251a may be formed on a portion of the upper surface 210A of the package substrate enclosed by the dam structure 260. In this case, the adhesive layer 251a may include a structure contacting an inner surface of the dam structure, but is not limited to the contact structure.

Next, referring to FIG. 10C, a semiconductor chip 220 may be prepared, and the semiconductor chip 220 may be mounted on the package substrate 210 so that the lower surface of the semiconductor chip 220 and the adhesive layer 251 face each other.

Next, the semiconductor package 100 illustrated in FIGS. 1A and 1B may be manufactured by performing a wire bonding process for connecting the chip pad 212 and the bonding pad 225 and a molded layer 290 forming process.

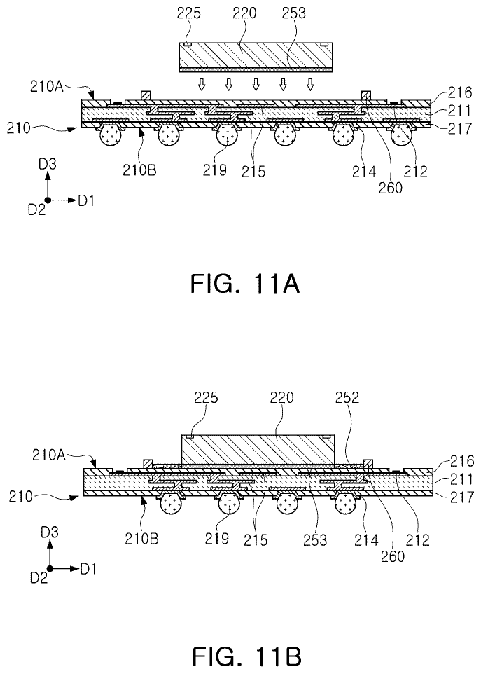

FIGS. 11A to 11B are drawings illustrating a manufacturing process of a semiconductor package according to an example embodiment. FIGS. 11A to 11B schematically illustrate the manufacturing process of the semiconductor package 200 according to the example embodiment illustrated in FIGS. 7A to 7B.

Referring to FIG. 11A, a semiconductor chip 220 having a lower surface to which an adhesive film 253 is attached may be prepared, and the semiconductor chip 220 may be disposed on a package substrate 210 so that the adhesive film 253 and an upper surface 210A of the package substrate face each other.

Referring to FIG. 11B, a polymer layer 252 may be applied between a dam structure 260 and a semiconductor chip 220 on the upper surface 210A of the package substrate to surround an outer surface of the adhesive film 253.

As set forth above, according to example embodiments of the present inventive concept, a semiconductor package having improved reliability and yield may be provided, by disposing an adhesive layer between a semiconductor chip and a substrate to be greater than an area of the semiconductor chip and an area of a region in which the external connection bumps are disposed.

The various and beneficial advantages and effects of the present inventive concept are not limited to the above-described content, and may be more easily understood through description of specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A semiconductor package, comprising:
a package substrate having an upper surface on which a plurality of bonding pads are arranged;
a semiconductor chip disposed on the package substrate, and having an upper surface on which a plurality of chip pads are arranged;
a plurality of bonding wires electrically connecting the plurality of bonding pads to the plurality of chip pads;
an adhesive layer disposed between the semiconductor chip and the package substrate and extending onto the upper surface of the package substrate;
a dam structure disposed around the adhesive layer, and at least a portion of the dam structure is in contact with a side surface of the adhesive layer;
a molded layer disposed on the upper surface of the package substrate, and covering at least a portion of each of the semiconductor chip and the plurality of bonding wires; and
external connection bumps disposed below the package substrate, and electrically connected to the plurality of bonding pads,
wherein the external connection bumps are located below a region covered by the adhesive layer of the package substrate, and
wherein an area of the adhesive layer is greater than an area of a region in which the external connection bumps are located.

2. The semiconductor package of claim 1, wherein a boundary of the semiconductor chip overlaps first external connection bumps disposed at the outermost side among the external connection bumps in a direction perpendicular to the package substrate.

3. The semiconductor package of claim 1, wherein the plurality of bonding pads are located on an exterior of the dam structure, and do not overlap the region in which the external connection bumps are located in a direction perpendicular to the package substrate.

4. The semiconductor package of claim 1, wherein a size of the region in which the external connection bumps are located is larger than a size of the semiconductor chip.

5. The semiconductor package of claim 1, wherein a size of a region in which the adhesive layer is located is the same as the size of the region in which the external connection bumps are located.

6. The semiconductor package of claim 1, further comprising:
at least one second semiconductor chip stacked on the upper surface of the semiconductor chip.

7. The semiconductor package of claim 1,
wherein the package substrate further comprises a solder resist layer, and
wherein a constituent material of the dam structure is the same as a constituent material of the solder resist layer.

8. The semiconductor package of claim 1, wherein an elastic modulus of the molded layer is greater than an elastic modulus of the adhesive layer.

9. The semiconductor package of claim 1, wherein an elastic modulus of the adhesive layer ranges from about 2,500 MPa to about 3,500 MPa.

10. The semiconductor package of claim 1, wherein the molded layer comprises an Epoxy Molding Compound (EMC).

11. The semiconductor package of claim 1, wherein the upper surface of the adhesive layer vertically overlaps a side surface of the semiconductor chip.

12. The semiconductor package of claim 1, wherein the dam structure has a shape in which a width of the dam structure gradually decreases in a direction toward the molded layer on the package substrate.

13. A semiconductor package, comprising:
a package substrate having an upper surface on which a plurality of bonding pads are arranged;
a semiconductor chip mounted on the upper surface of the package substrate, and having an upper surface on which a plurality of chip pads are arranged;
an adhesive layer disposed below the semiconductor chip, and extending onto the upper surface of the package substrate;
a dam structure disposed on the package substrate, and enclosing a side surface of the adhesive layer;
a plurality of bonding wires electrically connecting the plurality of bonding pads to the plurality of chip pads; and
a molded layer disposed on the upper surface of the package substrate, and covering at least a portion of each of the semiconductor chip and the plurality of bonding wires,
wherein a width of an area occupied by the adhesive layer and the dam structure is greater than a width of the semiconductor chip.

14. The semiconductor package of claim 13, wherein a thickness of the adhesive layer is smaller than a thickness of the dam structure.

15. The semiconductor package of claim 14, wherein the thickness of the dam structure ranges from about 10 μm to about 30 μm.

16. The semiconductor package of claim 14,
wherein the side surface of the adhesive layer is in contact with at least a portion of an inner surface of the dam structure, and
wherein a portion of a lower surface of the molded layer is disposed along a groove enclosed by a portion of the upper surface of the adhesive layer, the side surface of the semiconductor chip, and the inner surface of the dam structure.

17. The semiconductor package of claim 13, wherein the adhesive layer has extended portions respectively extending from each of four edges of the semiconductor chip on the upper surface of the package substrate.

18. The semiconductor package of claim 17, wherein, among the extended portions, portions extending from two first edges of the semiconductor chip, opposing each other, respectively have a first width, and portions extending from two second edges thereof have a second width, greater than the first width.

19. The semiconductor package of claim 18, wherein the plurality of bonding pads are arranged in a region adjacent to the two first edges of the semiconductor chip having the first width, and are not arranged in a region adjacent to the two second edges of the semiconductor chip.

20. A semiconductor package, comprising:
a package substrate having an upper surface on which a plurality of bonding pads are arranged;
a semiconductor chip disposed on the package substrate, and including an upper surface on which a plurality of chip pads are arranged, the semiconductor chip having a first area;
external connection bumps disposed below the package substrate, and electrically connected to the plurality of bonding pads;
an adhesive film disposed between the semiconductor chip and the package substrate and having an area equal to that of the first area;
a polymer layer disposed on the package substrate, and in contact with at least a portion of a side surface of the adhesive film, the polymer layer having a second area;
a dam structure protruding from the package substrate, and having an inner surface in contact with a side surface of the polymer layer;
a plurality of bonding wires electrically connecting the plurality of bonding pads to the plurality of chip pads; and
a molded layer disposed on the upper surface of the package substrate, and covering at least a portion of each of the semiconductor chip and the plurality of bonding wires.
